(19) United States
(12) Patent Application Publication
(10) Pub. No.: US 2009/0288709 A1
(43) Pub. Date: Nov. 26, 2009

(54) CONDUCTIVE PASTE FOR FORMING OF ELECTRODE OF CRYSTALLINE SILICON SUBSTRATE

(76) Inventors: Hideyo Iida, Niigata (JP); Toshiei Yamazaki, Niigata (JP); Kenichi Sakata, Niigata (JP)

Correspondence Address: FRISHAUF, HOLTZ, GOODMAN & CHICK, PC, 220 Fifth Avenue, 16TH Floor, NEW YORK, NY, 10001-7708, US

(21) Appl. No.: 12/448,539

(22) PCT Filed: Dec. 25, 2006
(86) PCT No.: PCT/JP2006/325739

§ 371 Date: Jun. 24, 2009

(51) Int. Cl. H01L 31/042; H01B 1/22

(52) U.S. Cl. 136/265; 252/512

(57) ABSTRACT

A conductive paste for forming electrodes, which makes it possible to form an electrode for a crystalline silicon substrate that is low in cost and has an equal degree of contact resistance and ohmic electrical contact, as compared to conventional silver electrode pastes, is obtained.

It is a conductive paste for forming an electrode for a crystalline silicon substrate, comprising conductive particles, glass frits, an organic binder and a solvent, in which conductive paste is characterized by comprising zinc particles as the conductive particles.

### TECHNICAL FIELD

The present invention relates to a conductive paste for forming an electrode for crystalline silicon substrate, particularly a conductive paste for forming an electrode for a crystalline silicon solar cell which utilize crystalline silicon such as single crystalline silicon or polycrystalline silicon as a substrate, and to a solar cell provided with an electrode produced by firing the conductive paste.

### BACKGROUND ART

Crystalline silicon substrates obtained by processing single crystalline silicon or polycrystalline silicon into a flat plate shape, are being widely used in devices such as solar cells or LSI devices. These devices have electrodes for obtaining electrical contact.

As an example, a cross-sectional schematic diagram of a crystalline silicon solar cell is presented in FIG. 1. A light incident side electrode 1 generally consists of bus electrodes and finger electrodes, and is formed by printing an electrode pattern of a conductive paste on an antireflection film 2 by a screen printing method or the like, and drying and firing the conductive paste. At the time of this firing, the light incident side electrode 1 can be formed to contact an n-type diffusion layer 3 formed on the surface of a crystalline silicon substrate 10, by making the conductive paste to fire through the antireflection film 2. Since light incidence does not have to occur from the back side of a p-type silicon substrate 4, a backside electrode 5 is formed over nearly the entire surface. A pn junction is formed at the interface between the p-type silicon substrate 4 and the n-type diffusion layer 3. Light such as solar light transmits through the antireflection film 2 and the n-type diffusion layer 3, and enters through the p-type silicon substrate 4, and during this process, light is absorbed so that electron-hole pairs are generated. These electron-hole pairs are separated by an electric field occurring at the pn junctions, with electrons being toward the light incident side electrode 1, while holes being toward the backside electrode 5. The electrons and holes are taken out to the outside as electric currents, through these electrodes.

In a crystalline silicon solar cell, the influence of electrodes on the characteristics of the solar cell, such as conversion efficiency, is large, and particularly the influence of the light incident side electrode is very large. This light incident side electrode is required to have sufficiently low contact resistance at the interface with the n-type diffusion layer, and to be in an ohmic electric contact. Furthermore, the electrical resistance of the electrode itself is needed to be sufficiently low, and it is also important that the resistance (conductor resistance) of the electrode material itself is low.

Also, in the case of the crystalline silicon solar cell shown in FIG. 1, generally, the optimal thickness of the n-type diffusion layer 3 is about 0.3 μm. Therefore, in regard to the formation of an electrode to the n-type diffusion layer 3, the thickness is required not to destroy the pn junctions, which are as shallow as about 0.3 μm.

Described above is an example of a crystalline silicon solar cell utilizing a p-type silicon substrate, but even in the case of using an n-type silicon substrate, a solar cell having a similar structure can be obtained only by employing a p-type diffusion layer, instead of the n-type diffusion layer for the p-type silicon substrate.

As an electrode material which fulfills the requirements of having low contact resistance and low conductor resistance, and not destroying shallow pn junctions, conductive pastes having silver as electrically conductive particles have been conventionally used. However, since silver is highly expensive and is a valuable material as a resource, in order to achieve cost reduction for electrodes, it is needed to reduce the proportion of use of silver in conductive pastes, or to substitute silver with an inexpensive metal other than silver. In recent years, as the amount of production of solar cells is rapidly increasing, a demand for cost reduction concerning the electrode materials for solar cells is growing stronger.

However, it is the current situation that no substantial development is implemented with regard to those conductive pastes which utilize conductive particles other than silver particles. For example, Patent Document 1 exemplifies conductive particles of copper, nickel and the like in addition to silver, but since silver particles are used in the pastes of specific embodiments, no description is given on the characteristics or the like of solar cells in the case of using conductive particles of copper, nickel and the like.

Patent Document 2 describes metallic additives such as Ti, Bi and Zn, but silver particles are used as conductive particles in the pastes of specific embodiments.

On the other hand, in the firing of the conductive pastes for electrode formation, firing in atmospheric air is preferred from the viewpoint of cost reduction. However, since metals other than noble metals are generally oxidized easily, firing in a reducing atmosphere is required, and there is also a problem that firing in atmospheric air is difficult.

Patent Document 1: Japanese Laid-open Patent [Kokai] Publication No. Hei 11-329070

Patent Document 2: Japanese Laid-open Patent [Kokai] Publication No. 2005-243500

### DISCLOSURE OF THE INVENTION

### Problems to be Solved by the Invention

An object of the present invention is to obtain a conductive paste for forming electrode, which is low in cost, and is capable of forming an electrode for a crystalline silicon substrate having an equal degree of contact resistance and ohmic electrical contact, as compared to conventional silver electrode pastes.

### Means for Solving the Problems

In order to obtain a conductive paste for forming electrodes for crystalline silicon substrates, which uses an inexpensive metal as a replacement for silver particles, investigation was devotedly conducted on conductive paste compositions which contain various metal particles. As a result, it was found that when an electrode for a crystalline silicon substrate is formed by firing the conductive paste including zinc particles of the present invention in atmospheric air, an electrode which has low ohmic contact resistance and does not destroy shallow pn junctions, can be obtained. It was also found that such electrical characteristics are not observed in the case of conductive pastes using copper, nickel, iron, aluminum and tin respectively alone, and zinc is a metal which is singular for obtaining the effects of the present invention, among various metals. Thus, the present invention was achieved based on these findings.

That is, the present invention is a conductive paste for forming electrodes for crystalline silicon substrates, comprising conductive particles, glass frits, an organic binder, and a solvent, characterized in that the conductive paste comprises zinc particles as the conductive particles. Preferably, the invention is a conductive paste further including copper particles as the conductive particles. Also, preferably, the invention is a conductive paste in which the weight proportion of the zinc particles and the copper particles is 2:1 to 2:3. Also, preferably, the invention is a conductive paste further including at least one metal oxide selected from zinc oxide, cuprous oxide and cupric oxide. More preferably, the invention is a conductive paste in which the metal oxide is comprised in an amount of 0.5 to 5 parts by weight relative to 100 parts by weight of the zinc particles.

Furthermore, the present invention is a conductive paste for forming an electrode for crystalline silicon solar cells, which is the above-described conductive paste.

Furthermore, the present invention is a crystalline silicon solar cell having an electrode formed by firing the conductive paste. Preferably, the invention is a crystalline silicon solar cell in which the electrode has a layer of an alloy of zinc and copper. Also, preferably, the invention is a crystalline silicon solar cell further having a soldering pad part, in which the electrode and the soldering pad part are arranged to be in electrical contact. Furthermore, preferably, the invention is a crystalline silicon solar cell in which the electrode and a lead wire for electrically connecting a plurality of crystalline silicon solar cells, are connected with a conductive adhesive.

### EFFECTS OF THE INVENTION

When the conductive paste for forming electrode of the present invention is used, it is possible to form an electrode for a crystalline silicon substrate, which is low in cost, and has an equal degree of contact resistance and ohmic electrical contact, as compared to conventional silver electrode pastes.

### BRIEF DESCRIPTION OF THE DRAWINGS

FIG. 1 is a cross-sectional schematic diagram of a crystalline silicon solar cell.

FIG. 2 is a schematic diagram of the light incident side surface of a solar cell having an electrode which uses the conductive paste of the present invention and a solderable pad part in arrangement, and cross-sectional views thereof.

FIG. 3 is a diagram showing the current-voltage characteristics in the dark of a solar cell using the conductive paste of Example 1.

FIG. 4 is a diagram showing the relationship between the FF of a solar cell using the conductive paste of Example 2, and the weight proportion of copper relative to the proportion of zinc taken as 10.

FIG. 5 is a diagram showing the relationship between the FF of a solar cell using the conductive paste of Example 3, and the firing temperature for the conductive paste.

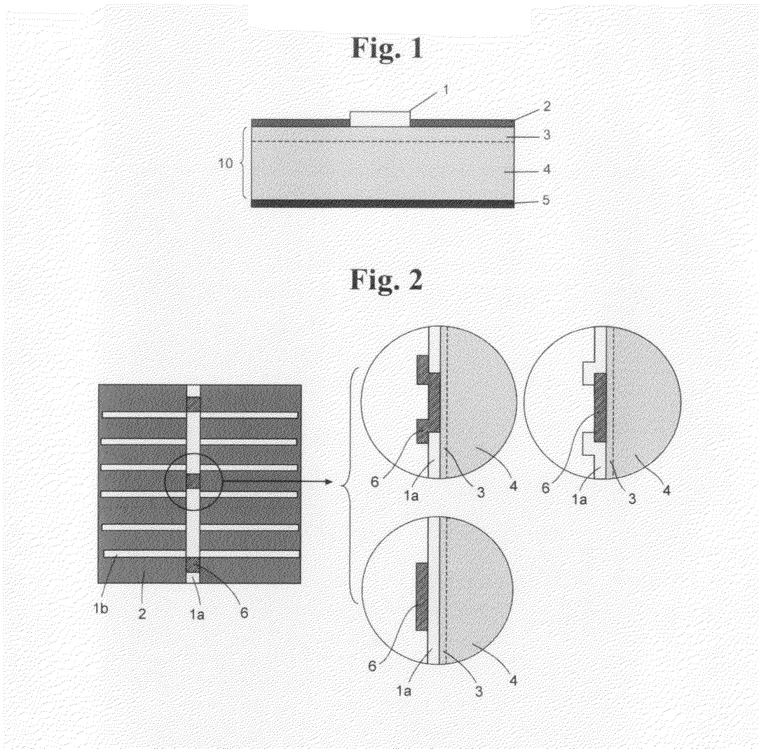

### REFERENCE NUMERALS

1 Light incident side electrode
1a Bus electrode
1b Finger electrode
2 Antireflection film
3 n-type diffusion layer
4 p-type silicon substrate
5 Backside electrode
6 Soldering pad part
10 Crystalline silicon substrate

### BEST MODE FOR CARRYING OUT THE INVENTION

In the present specification, the “crystalline silicon” comprises single crystalline or polycrystalline silicon. The “crystalline silicon substrate” means a material obtained by shaping crystalline silicon into a shape appropriate for device formation, such as a flat plate shape, for the formation of electric devices or the electronic devices. As for the method for producing the crystalline silicon, any method may be used. For example, in the case of single crystalline silicon, the Czochralski method can be used, while in the case of polycrystalline silicon, a casting method can be used. Furthermore, a polycrystalline silicon ribbon produced by some other production method, for example, a ribbon pulling method, polycrystalline silicon formed on a heterogeneous substrate such as glass, and the like, can also be used as the crystalline silicon substrate. Furthermore, the “crystalline silicon solar cell” means a solar cell produced by using a crystalline silicon substrate. As an index indicating the solar cell performance, a fill factor (hereinafter, abbreviated to “FF”), which is obtainable from the measurement of the current-voltage characteristics under photo irradiation, is used. In general, in the case where FF is 0.6 or greater, the solar cell can be said to have good performance. If FF is 0.7 or greater, the solar cell can be said to have better performance.

The conductive paste of the present invention comprises conductive particles, glass frits, an organic binder and a solvent, and its feature lies in that the paste comprises zinc particles as the conductive particles. A conductive paste including zinc particles as the conductive particles forms favorable ohmic contact. Although the reason is not clear, the co-existence of surface oxide film of zinc particles (zinc oxide), molten glass frits and the like is preferred in the process of firing the conductive paste. It is conceived that when the conductive paste of the present invention is used in the formation of an electrode for crystalline silicon solar cells, such co-existence has an effective action on the firing-through of the antireflection film. Furthermore, in order to decrease the conductor resistance of the electrode, it is preferable that the conductive particles further comprise copper particles.

The shape and particle dimension of the zinc particles comprised in the conductive particles are not particularly limited. As for the shape, for example, a spherical shape, a scale shape and the like can be used. The particle dimension means the dimension of the maximum length part of a single particle. The particle dimension is preferably 0.05 to 20 μm, and more preferably 0.1 to 5 μm, from the viewpoint of workability and the like. In general, since the dimension of micro particles has a certain distribution, not all zinc particles need to have the aforementioned particle dimension, and it is preferable that the particle dimension of the 50% cumulative value of all particles (D50) be in the above-mentioned range of particle dimension. Furthermore, the mean value of the particle dimension (average particle dimension) may also be in the above-described range.

The conductive paste of the present invention can further comprise metal particles other than zinc particles as the conductive particles. In order to obtain more satisfactory electrode performance, it is preferred that the conductive paste further comprises copper particles as the metal particles other than zinc particles. When the conductive paste comprises copper particles, it is thought that the sinterability between the conductive particles is improved, and thus the conductor resistance of the electrode is decreased. It is also thought that the fact that the electrical resistivity of copper is lower than that of zinc, is also a reason for the copper particles contributing to a decrease in the conductor resistance of the electrode.

The range of ratio of zinc and copper to exhibit satisfactory solar cell characteristics, that is, a high FF, is preferably such that, in the case of firing in atmospheric air, the weight proportion of zinc particles:copper particles is in the range of 2:1 to 2:3. In the case of firing in a nitrogen atmosphere, a region of higher content of copper particles in the above-mentioned range, for example, the range of 1:1 to 2:3, is preferred.

The shape and particle dimension of the copper particles are not particularly limited. As for the shape, for example, a spherical shape, a scale shape and the like can be used. The particle dimension is preferably 0.05 to 10 μm, and more preferably 0.1 to 5 μm, from the viewpoint of workability and the like. In general, since the dimension of micro particles has a certain distribution, not all copper particles need to have the aforementioned particle dimension, and it is preferable that the particle dimension of the 50% cumulative value of all particles (D50) be in the above-mentioned range of particle dimension.

In addition, although it is preferable that the conductive particles consist of zinc particles, or of zinc particles and copper particles, the conductive particles may also comprise other metal particles within the scope of not impairing the effects of the present invention. For example, satisfactory electrode performance can be obtained even if silver particles are added to zinc particles, or copper particles and silver particles are added to zinc particles. However, from the viewpoint of costs and the like, it is preferable that the conductive particles do not substantially comprise silver particles. Furthermore, the conductive particles may occasionally comprise metals other than zinc and copper as generally incorporated impurities.

In the case where the conductive paste of the present invention further comprises various metal oxides, stable and satisfactory electrode performance can be obtained. It is preferable for the conductive paste to comprise at least one particularly among the oxides of zinc and copper, that is, among metal oxides of zinc oxide (ZnO) and copper oxides (cuprous oxide: Cu₂O, and cupric oxide: CuO), as the metal oxide. It is conceived that the metal oxide controls sinterability of the conductive particles in the firing process, or controls the expansion of liquefied glass frits, and contributes to obtaining a contact between the conductive particle, particularly zinc and the semiconductor surface. For that reason, the amount of addition of the metal oxide in, the conductive paste of the present invention is preferably 0.5 to 5 parts by weight relative to 100 parts by weight of zinc particles.

The shape of the metal oxide is not particularly limited, and a spherical type, an amorphous type and the like can be used. The particle dimension is not particularly limited, but is preferably 0.1 to 5 μm from the viewpoint of dispersibility or the like. In general, since the dimension of micro particles has a certain distribution, not all metal oxide particles need to have the above-mentioned particle dimension, and it is preferable that the particle dimension of the 50% cumulative value of all particles (D50) be in the above-mentioned range of particle dimension. Furthermore, the mean value of the particle dimension (average particle dimension) may also be in the above-mentioned range.

The organic binder and the solvent take the role of adjusting the viscosity of the conductive paste, or the like, and thus both of them are not particularly limited. The organic binder can also be used in the state of being dissolved in the solvent.

As the organic binder, cellulose-based resins (for example, ethyl cellulose, nitrocellulose, and the like) and (meth)acrylic resins (for example, polymethyl acrylate, polymethyl methacrylate, and the like) can be used.

As the solvent, alcohols (for example, terpineol, α-terpineol, β-terpineol, and the like) and esters (for example, hydroxyl group-containing esters, 2,2,4-trimethyl-1,3-pentanediol monoisobutyrate, butylcarbitol acetate, and the like) can be used.

The amounts of the organic binder and the solvent can be appropriately selected in accordance with the desired viscosity or the like. For example, the amount of addition of the solvent is usually 0.5 to 20 parts by weight, and preferably 10 to 20 parts by weight, relative to 100 parts by weight of the conductive particles.

As for the glass frits, Pb-based glass frits (for example, a PbO—B₂O₃—SiO₂ system, and the like), and Pb-free glass frits (for example, a Bi₂O₃—B₂O₃—SiO₂—CeO₂—LiO₂—NaO₂ system and the like) can be used, but the examples are not limited to these. The shape of the glass frits is not particularly limited, and for example, a spherical shape, an amorphous type, or the like can be used. Furthermore, the particle dimension is also not particularly limited, but from the viewpoint of workability or the like, the mean value of the particle dimension (average particle dimension) is preferably in the range of 0.01 to 10 μm, and more preferably in the range of 0.05 to 1 μm. The amount of addition is usually 0.1 to 10 parts by weight, and preferably 1 to 5 parts by weight, relative to 100 parts by weight of the conductive particles.

Moreover, the conductive paste of the present invention can be incorporated, if necessary, with a plasticizer, a defoaming agent, a dispersant, a leveling agent, a stabilizer, an adhesion promoting agent, and the like as additives. Among these, as for the plasticizer, phthalic acid esters, glycolic acid esters, phosphoric acid esters, sebacic acid esters, adipic acid esters, citric acid esters, and the like can be used.

The conductive paste for forming electrode for crystalline silicon substrates of the present invention can be produced by adding conductive particles to an organic binder and a solvent, and further adding, as necessary, a metal oxide, glass frits and other additives, followed by mixing and further dispersing of the components.

The mixing is performed with, for example, a planetary mixer. Furthermore, the dispersing can be performed by a three roll mill. The mixing and dispersing are not limited to these methods, and various existing methods can be used.

The conductive paste of the present invention is particularly preferably a conductive paste for forming electrode for crystalline silicon solar cells. Therefore, it is preferable that a crystalline silicon solar cell have an electrode obtainable by firing the conductive paste of the present invention. The conductive paste of the present invention forms an electrode having low conductor resistance, as the zinc particles and copper particles are sintered while forming an alloy layer, during the firing process carried out at a firing temperature of 500 to 850° C. In particular, since zinc has a low melting point, zinc melts in the early stage of the firing process, and penetrates between copper particles, thus forming an alloy layer with copper.

Since the conductive paste of the present invention contains zinc, a problem may arise that upon forming an electrode on a crystalline silicon substrate, soldering to the electrode is difficult. In such a situation, this problem can be solved by adopting a structure having a soldering pad part, which enables soldering, arranged to be in electrical contact with the electrode. Such structure will be described by taking an example of the case of crystalline silicon solar cell, using FIG. 2. The light incident side electrode consists of a bus electrode 1a and a finger electrode 1b, but the soldering pad part 6 is arranged to be in electrical contact with the bus electrode 1a. As shown by the three types of cross-sectional structures in FIG. 2, the formation of the soldering pad part 6 may be carried out such that the soldering pad part is first formed and then the electrode is formed, or may also be carried out in a reverse order. In addition, the bus electrode 1a, the finger electrode 1b and the soldering pad part 6 can be formed to be in contact with the n-type diffusion layer 3, since the conductive paste is fire through the antireflection film during firing the conductive paste.

Alternatively, a lead wire for electrically connecting a plurality of crystalline silicon solar cells, can be connected to the electrode by means of a conductive adhesive. The conductive adhesive is not particularly limited, and can be produced by, for example, providing a mixture of an epoxy resin and a phenolic resin at a weight ratio of about 6:4, adding an imidazole as a curing catalyst in an amount of about 2% by weight of the total resin content, adding silver particles to reach a proportion of about 80% by weight of the total weight of the conductive adhesive, and dispersing the mixture with a three roll mill. It is also acceptable to add copper particles in place of silver particles, to the same resin blend.

The method for forming an electrode for crystalline silicon substrates using the conductive paste of the present invention, will be described by taking the case of a producing method of a crystalline silicon solar cell utilizing a p-type silicon substrate, as an example. First, the conductive paste of the present invention is printed on a crystalline silicon substrate having an n-diffusion layer on the surface or on an antireflection film formed on the n-diffusion layer of a crystalline silicon substrate, by a method such as a screen printing method, and the paste is dried at a temperature of about 100 to 150° C. for several minutes. Similarly, a conductive paste containing aluminum as a main component is printed on the back side over nearly the entire surface, and is dried. Subsequently, the assembly is fired using a furnace such as a tubular furnace, in atmospheric air at a temperature of about 500 to 850° C. for several minutes, to form a light incident side electrode and a backside electrode. In the case where a conductive paste having a predetermined composition is printed on an antireflection film, since the paste material at high temperature fires through the antireflection film during the firing process, the electrode can be formed on the silicon substrate. In addition, the firing conditions are not limited to the conditions described above, and can be appropriately selected.

Even for a solar cell having a structure of entire backside electrode type (so-called a back contact structure), or a structure in which the light incident side electrode is conducted to the back side through a through-hole provided in the substrate, an electrode can be formed using the conductive paste of the present invention.

An example of a solar cell utilizing a p-type silicon substrate has been described above, but also in the case of a crystalline silicon solar cell utilizing an n-type silicon substrate, a solar cell can be produced by a similar process using the conductive paste of the present invention, except for the difference that the impurities for forming a diffusion layer are changed from n-type impurities such as phosphorus, to p-type impurities such as boron, and a p-type diffusion layer is formed instead of an n-type diffusion layer. Furthermore, even in the case of using any of a single crystalline silicon substrate or a polycrystalline silicon substrate, the conductive paste of the present invention can be used to exert the effects of the present invention.

The conductive paste of the present invention can be used in any device in which an electrode is formed on a crystalline silicon substrate, without being limited to crystalline silicon solar cells.

### EXAMPLES

Hereinafter, the present invention will be described in detail by way of Examples, but the present invention is not intended to limited to these.

### Example 1

The conductive pastes of Example 1-1 and Comparative Examples 1-1 to 1-4 were prepared by mixing the components indicated in Table 1 with a planetary mixer, and dispersing the mixture with a three roll mill to form a paste.

The evaluation of the conductive paste of the present invention was carried out by fabricating a solar cell using the respective conductive pastes of the Example and Comparative Examples, and measuring the characteristics. The method of fabricating a solar cell is as follows.

As the crystalline silicon substrate, a substrate of the Czochralski (CZ) method, a diameter of 3 inches, a (0001) plane, B-doped p-type single crystalline silicon substrate, a specific resistance of about 3 Ω·cm, and a substrate thickness of 200 μm, was used.

First, a silicon oxide layer having a thickness of about 20 μm was formed on the substrate by dry oxidation, and then the layer was etched with a solution prepared by mixing hydrogen fluoride, pure water and ammonium fluoride, to eliminate damages on the surface of the substrate.

Subsequently, a pyramidal textured structure was formed on one side by a wet etching method (aqueous solution of sodium hydroxide), and then the structure was washed with an aqueous solution containing hydrochloric acid and hydrogen peroxide. Subsequently, phosphorus was diffused on the texture-formed surface according to a gas phase diffusion method, using phosphorus oxychloride (POCl₃), at a temperature of 1000° C. for 20 minutes, to form an n-type diffusion layer having a depth of about 0.3 μm.

Subsequently, a mixed gas of NH₃/SiH₄=0.5 was subjected to glow discharge decomposition at 1 Torr (133 Pa), and thereby, a silicon nitride film (antireflection film) having a film thickness of about 70 nm was formed by a plasma CVD method. After this, the substrate was cut with a dicer to 15 mm squares, and thus cell substrates were obtained.

For the formation of a light incident side electrode, the respective conductive pastes of the Example and Comparative Examples were each screen printed on the antireflection film made of a silicon nitride film of the cell substrate, using a 250-mesh screen mask made of stainless steel. At this time, the screen printing was conducted using a screen mask pattern which consists of a bus electrode and a finger electrode, so that the film thickness of the conductive paste would be about 20 μm. Thereafter, the conductive paste was dried at 150° C. for 1 minute.

Subsequently, for the formation of a backside electrode, a conductive paste containing aluminum particles, glass frits, ethyl cellulose and a solvent as the main components was printed on the back side over nearly the entire surface by a screen printing method, and the conductive paste was dried at 150° C. for 1 minute.

Thereafter, using a tubular furnace capable of controlling various atmospheres, the cell substrate was fired in atmospheric air at a temperature of 700° C. for 2 minutes, to form a light incident side electrode and a backside electrode, and thus a solar cell was obtained.

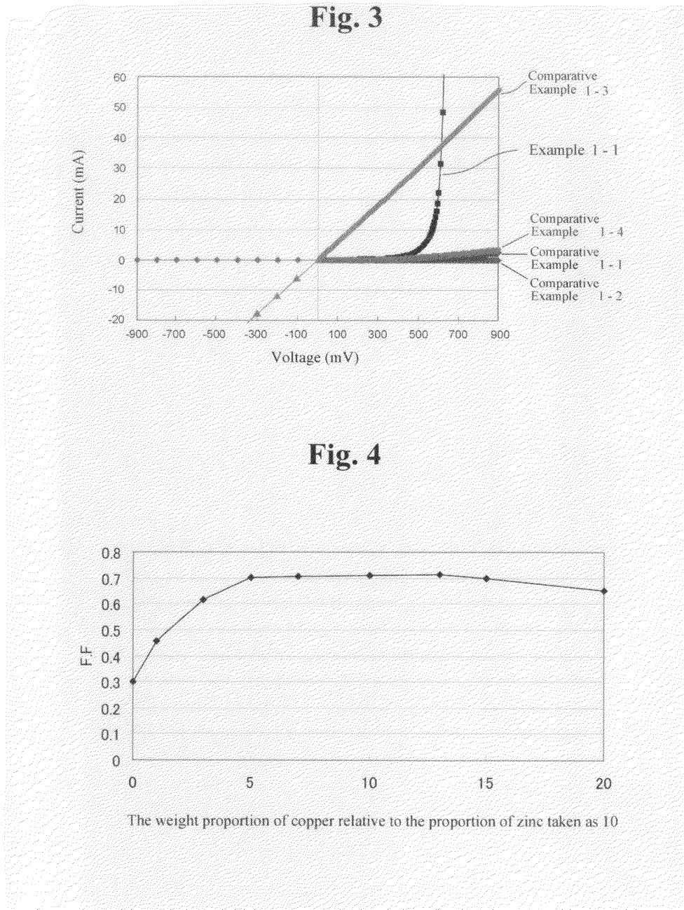

The current-voltage characteristics in the dark of the solar cell thus produced were measured. Specifically, without light irradiation, voltages of −0.9 V to +0.9 V were applied between the electrodes on the front and back sides of the solar cell, and the currents for the applied voltages were measured. The measurement results are presented in FIG. 3. As it is obvious from this diagram, when the conductive paste of Example 1 which contained zinc particles as the conductive particles was used, satisfactory rectifiability was exhibited. On the other hand, when the conductive pastes of Comparative Examples which contained metal particles other than zinc as the conductive particles were used, satisfactory rectifiability was not exhibited. From these results, it was confirmed that the conductive paste of the present invention could form an electrode for crystalline silicon substrates having low contact resistance, without exerting adverse effects on the pn junctions, even if firing is performed in atmospheric air.

TABLE 1

| | | Example | Comparative Example | | | |
|---|---|---|---|---|---|---|
| Component: parts by weight | | 1-1 | 1-1 | 1-2 | 1-3 | 1-4 |
| Conductive | Zinc | 100 | — | — | — | — |
| particles | Copper | — | 100 | — | — | — |
| | Nickel | — | — | 100 | — | — |
| | Aluminum | — | — | — | 100 | — |
| | Tin | — | — | — | — | 100 |
| Organic binder | Ethyl cellulose | 3 | 3 | 3 | 3 | 3 |
| Solvent | 2,2,4-Trimethyl-1,3-pentadiol | 13 | 13 | 13 | 13 | 13 |
| | monoisobutyrate | | | | | |
| Glass frits | Lead borosilicate-based glass | 2.5 | 2.5 | 2.5 | 2.5 | 2.5 |
| Rectifiability | | Present | Absent | Absent | Absent | Absent |

Zinc particles (manufactured by Honjo Chemical Corp.): average particle dimension 10 μm
Copper particles (manufactured by Mitsui Mining & Smelting Co., Ltd.): spherical, average particle dimension 3 μm
Nickel particles (manufactured by Toho Titanium Co., Ltd.): average particle dimension 1 μm
Aluminum particles (manufactured by Yamaishi Metal Co., Ltd.): average particle dimension 10 μm
Tin particles (manufactured by Yamaishi Metal Co., Ltd.): average particle dimension 3 μm
Lead borosilicate-based glass: amorphous type, average particle dimension 0.1 μm

### Example 2

Conductive pastes of Examples 2-1 to 2-9 were prepared by using a mixture of zinc particles and copper particles at the weight proportions indicated in Table 2 as the conductive particles, instead of the conductive particles of Table 1 for the conductive paste of Example 1, and incorporating 2.5 parts by weight of zinc oxide, which is a metal oxide, with respect to 100 parts by weight of the zinc particles. Furthermore, 3 parts by weight of an organic binder, 13 parts by weight of a solvent, and 2.5 parts by weight of glass frits, all of the same kind as those used in Example 1, were incorporated with respect to 100 parts by weight of the conductive particles. Solar cells were fabricated in the same manner as in Example 1, and the current-voltage characteristics were measured under irradiation of solar simulator light (AM1.5 energy density 100 mW/cm²), so that the FF was calculated from the measurement results.

As the results are shown in Table 2 and FIG. 4, the solar cells of Examples 2-1 to 2-9 operated, and satisfactory electrical contact could be obtained. Particularly, when the weight proportion of zinc:copper was in the range of 10:5 to 10:15 (2:1 to 2:3), a favorable solar cell characteristic of FF being 0.7 or greater was exhibited. This is thought to be because the addition of copper particles caused a decrease in the conductor resistance of the electrode.

TABLE 2

| | Example | | | | | | | | |
|---|---|---|---|---|---|---|---|---|---|
| | 2-1 | 2-2 | 2-3 | 2-4 | 2-5 | 2-6 | 2-7 | 2-8 | 2-9 |
| Weight proportion | 10:0 | 10:1 | 10:3 | 10:5 | 10:7 | 10:10 | 10:13 | 10:15 | 10:20 |
| of conductive | | | | | | | | | |
| particles | | | | | | | | | |
| (zinc:copper) | | | | | | | | | |
| FF | 0.257 | 0.397 | 0.568 | 0.701 | 0.758 | 0.765 | 0.734 | 0.703 | 0.543 |

### Example 3

Conductive pastes of Examples 3-2 to 3-4 were prepared by using conductive particles having a weight proportion of zinc:copper of 10:7, and adding 1 part by weight of the metal oxide indicated in Table 3 with respect to 100 parts by weight of the zinc particles. At this time, a conductive paste of Example 3-1 which did not contain any metal oxide was also produced. The conductive pastes of Examples 3-1 to 3-4 comprised 3 parts by weight of an organic binder, 13 parts by weight of a solvent, and 2.5 parts by weight of glass frits, all of the same kind as those used in Example 1, with respect to 100 parts by weight of the conductive particles. Furthermore, solar cells were fabricated in the same manner as in Example 1, using the conductive pastes of Examples 3-1 to 3-4, except that the firing temperature for the cell substrate was changed as indicated in Table 3. Furthermore, the characteristics of the solar cells were evaluated by the same method as in Example 2.

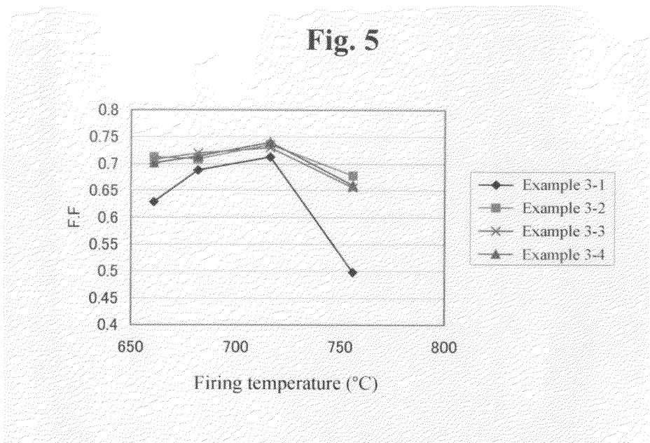

As the results are shown in Table 3 and FIG. 5, favorable FF values could be obtained in all of the Examples. Particularly, in the cases of the Examples 3-2 to 3-4 where a metal oxide was added, more satisfactory results of FF being enhanced were obtained, as compared to the case of Example 3-1 where metal oxide was not added. In addition, even when the amount of addition of the respective metal oxides was changed in the range of 0.5 to 5 parts by weight for the conductive pastes of the Example 3-2 to 3-4, the same FF-improving effects could be obtained. Furthermore, also in the case of using various metal oxides (zinc oxide, cuprous oxide, and cupric oxide) in combination, the same FF-improving effects could be obtained when the total amount of addition was in the range of 0.5 to 5 parts by weight.

TABLE 3

| | | Example | | | |
|---|---|---|---|---|---|
| | | 3-1 | 3-2 | 3-3 | 3-4 |
| Metal oxide | Zinc oxide (ZnO) | — | 1 | — | — |
| (parts by | Cuprous oxide (Cu₂O) | — | — | 1 | — |
| weight with | Cupric oxide (CuO) | — | — | — | 1 |
| respect | | | | | |
| to 100 parts | | | | | |
| by weight of | | | | | |
| zinc | | | | | |
| particles) | | | | | |
| FF | Firing temperature 660° C. | 0.693 | 0.751 | 0.731 | 0.728 |
| | Firing temperature 680° C. | 0.734 | 0.772 | 0.759 | 0.752 |
| | Firing temperature 720° C. | 0.755 | 0.778 | 0.767 | 0.765 |
| | Firing temperature 760° C. | 0.751 | 0.774 | 0.761 | 0.758 |

### Example 4

In order to solve the problem concerning solderability of the conductive paste of the present invention, an experiment was performed to implement connection between solar cells using a soldering pad part capable of soldering and a conductive adhesive.

The results of tensile strength tests for three types of connections, such as soldered connection via a soldering pad part with a fired type silver paste, connection using a silver conductive adhesive, and connection using a copper conductive adhesive, were compared with the tensile strength in the case of a silver electrode produced using a conductive paste which did not comprise any metal other than silver.

The fired type silver paste for forming a soldering pad part was produced by dispersing ethyl cellulose, glass and silver particles (weight ratio 4:2:100) with a three roll mill (paste A).

The conductive adhesive was produced by providing a mixture of epoxy resin:phenol resin (weight ratio 6:4), adding an imidazole as a curing catalyst in an amount of 2% by weight of the total resin content, adding silver particles to a content of 80% by weight of the total weight of the conductive adhesive, and dispersing the resulting mixture with a three roll mill (paste B). A paste C was produced in the same manner as in the case of paste B, except that copper particles were used instead of silver particles.

The conductive paste of 3-2 of Example 3 was used to form a bus electrode on the same single crystalline silicon substrate as that used in Example 1, by firing at 720° C. Subsequently, onto this bus electrode, the pastes A, B and C were printed to a size of 2 mm×12 mm. After a soldering pad part was formed by firing the paste A at a high temperature of 700° C., flux was coated, a solder drawn copper ribbon wire (2 mm in width, thickness 250 μm) was mounted, and soldering was performed at 250° C. for 1 minute. For the pastes B and C, after coating and before drying, a copper ribbon wire was placed on each of the pastes sized to 2 mm×12 mm, and the paste was cured under a load of 200 g, at a temperature of 200° C. for 30 minutes. As a Comparative Example, measurement was made of the tensile strength for the case of using a conventional fired type silver-based electrode containing silver only as the conductive particles, and the tensile strength of each of the pastes was normalized on the basis of the aforementioned value for comparison. As it is obvious from the results shown in Table 4, in the case of using the pastes A, B and C, there could be obtained tensile strengths of an equal extent to that of the conventional structure, which was the Comparative Example.

TABLE 4

| | | | | Comparative |
|---|---|---|---|---|
| | Paste A | Paste B | Paste C | Example |
| Normalized tensile strength | 0.95 | 0.92 | 0.90 | 1 |

### INDUSTRIAL APPLICABILITY

The present invention can be used in the formation of an electrode for devices making use of crystalline silicon substrates, and particularly in the formation of an electrode for crystalline silicon solar cells.

1. A conductive paste for forming an electrode for a crystalline silicon substrate, comprising conductive particles, glass frits, an organic binder and a solvent, wherein the conductive paste comprises zinc particles as the conductive particles.

2. The conductive paste according to claim 1, further comprising copper particles as the conductive particles.

3. The conductive paste according to claim 2, wherein the weight proportion of the zinc particles and the copper particles is 2:1 to 2:3.

4. The conductive paste according to claim 1, further comprising at least one metal oxide selected from zinc oxide, cuprous oxide and cupric oxide.

5. The conductive paste according to claim 4, wherein the metal oxide is contained in a proportion of 0.5 to 5 parts by weight relative to 100 parts by weight of the zinc particles.

6. A conductive paste for forming an electrode for a crystalline silicon solar cell, which is the conductive paste according to claim 1.

7. A crystalline silicon solar cell having an electrode produced by firing the conductive paste according to claim 6.

8. The crystalline silicon solar cell according to claim 7, wherein the electrode has a layer of an alloy of zinc and copper.

9. The crystalline silicon solar cell according to claim 7, further comprising a soldering pad part, wherein the electrode and the soldering pad part are arranged to be in electrical contact.

10. The crystalline silicon solar cell according to claim 7, wherein the electrode and a lead wire for electrically connecting a plurality of crystalline silicon solar cells, are connected with a conductive adhesive.
